(19) United States
(12) Patent Application Publication
(10) Pub. No.: US 2023/0197501 A1
(43) Pub. Date: Jun. 22, 2023

(54) PLASMA PROCESSING APPARATUS

(71) Applicant: TOKYO ELECTRON LIMITED, Tokyo (JP)

(72) Inventors: Takehiro UEDA, Miyagi (JP); Kenji Nagai, Miyagi (JP)

(73) Assignee: TOKYO ELECTRON LIMITED, Tokyo (JP)

(21) Appl. No.: 18/108,391

(22) Filed: Feb. 10, 2023

Related U.S. Application Data
(63) Continuation of application No. 15/961,381, filed on Apr. 24, 2018.

(30) Foreign Application Priority Data
Apr. 26, 2017 (JP) 2017-087052
Jan. 5, 2018 (JP) 2018-000367

(51) Int. Cl. H01L 21/687; H01L 21/67; H01J 37/32; H01L 21/683

(52) U.S. Cl. CPC H01L 21/68764; H01L 21/67069; H01L 21/67259; H01J 37/32642; H01J 37/32513; H01J 37/32715; H01L 21/67103; H01L 21/67109; H01L 21/6831; H01L 21/68742; H01L 21/68735; H01L 21/67248; H01J 2237/3344

(57) ABSTRACT

A plasma processing apparatus includes a first mounting table on which a target object to be processed is mounted, a second mounting table provided around the first mounting table, and an elevation mechanism. A focus ring is mounted on the second mounting table. The second mounting table has therein a temperature control mechanism. The elevation mechanism is configured to vertically move the second mounting table.

### CROSS-REFERENCE TO RELATED APPLICATIONS

This is a continuation application of U.S. application Ser. No. 15/961,381, filed Apr. 24, 2018, which claims priority to Japanese Patent Application No. 2017-087052 filed Apr. 26, 2017, and Japanese Patent Application No. 2018-000367 filed Jan. 5, 2018, respectively, the entire contents of which are incorporated herein by reference, and priority is claimed to each of the foregoing.

### FIELD OF THE INVENTION

The disclosure relates to a plasma processing apparatus.

### BACKGROUND OF THE INVENTION

Conventionally, there is known a plasma processing apparatus for performing plasma processing such as etching or the like on a target object such as a semiconductor wafer (hereinafter, referred to as “wafer”) by using a plasma. In this plasma processing apparatus, when the plasma processing is performed, parts in a chamber are consumed. For example, a focus ring, which is provided to surround the wafer for a uniform plasma, may be close to the plasma and thus is consumed quickly. The degree of consumption of the focus ring greatly affects a result of processing on the wafer. For example, when a height position of a plasma sheath above the focus ring is deviated from a height position of a plasma sheath above the wafer, etching characteristics in an outer peripheral portion of the wafer deteriorate, which affects uniformity or the like. Therefore, when the focus ring is consumed to a certain extent, the plasma processing apparatus is exposed to the atmosphere and the focus ring is replaced.

However, if the plasma processing apparatus is exposed to the atmosphere, time for maintenance is increased.

Further, in the plasma processing apparatus, when the frequency of part replacement is increased, productivity decreases and a cost increases.

Therefore, there has been proposed a technique for raising the focus ring by a drive mechanism so that heights of the wafer and the focus ring can be maintained at a constant level (see, e.g., Japanese Patent Application Publication No. 2002-176030).

However, when the consumed focus ring is raised, the focus ring is separated from the mounting surface. In the plasma processing apparatus, when the focus ring is separated from the mounting surface, it is not possible to remove the inputted heat. As a consequence, a temperature of the focus ring is increased and the etching characteristics may be changed. As a result, in the plasma processing apparatus, the uniformity of plasma processing on the target object is decreased.

### SUMMARY OF THE INVENTION

In accordance with an aspect of the present disclosure, there is provided a plasma processing apparatus including a first mounting table, a second mounting table and an elevation mechanism. A target object to be processed is mounted on the first mounting table. The second mounting table is provided around the first mounting table and a focus ring is mounted on the second mounting table. The second mounting table has therein a temperature control mechanism. The elevation mechanism is configured to vertically move the second mounting table.

In accordance with one embodiment of the disclosed plasma processing apparatus, it is possible to suppress deterioration in the uniformity of the plasma processing on the target object.

### BRIEF DESCRIPTION OF THE DRAWINGS

The objects and features of the disclosure will become apparent from the following description of embodiments, given in conjunction with the accompanying drawings, in which:

FIG. 1 is a schematic cross sectional view showing a schematic configuration of a plasma processing apparatus according to an embodiment;

FIG. 2 is a schematic cross sectional view showing configurations of principal parts of a first mounting table and a second mounting table according to a first embodiment;

FIG. 3 is a top view of the first mounting table and the second mounting table which is viewed from the top;

FIG. 4 shows a reflection system of laser light;

FIG. 5 shows an example of distribution of detected intensities of light;

FIGS. 6A to 6C explain an example of a sequence of raising the second mounting table;

FIG. 7 shows an example of a configuration of a comparative example;

FIG. 8 shows an example of changes in etching characteristics;

FIG. 9 is a perspective view showing a main configuration of a first mounting table and a second mounting table according to a second embodiment; and

FIG. 10 is a schematic cross sectional view showing configurations of principal parts of the first mounting table and the second mounting table according to the second embodiment.

### DETAILED DESCRIPTION OF THE EMBODIMENTS

Hereinafter, embodiments of a plasma processing apparatus of the present disclosure will be described in detail with reference to the accompanying drawings. Like reference numerals will be used for like or corresponding parts throughout the drawings. The embodiments are not intended to limit the present disclosure. The embodiments can be appropriately combined without contradicting processing contents.

### First Embodiment

(Configuration of Plasma Processing Apparatus)

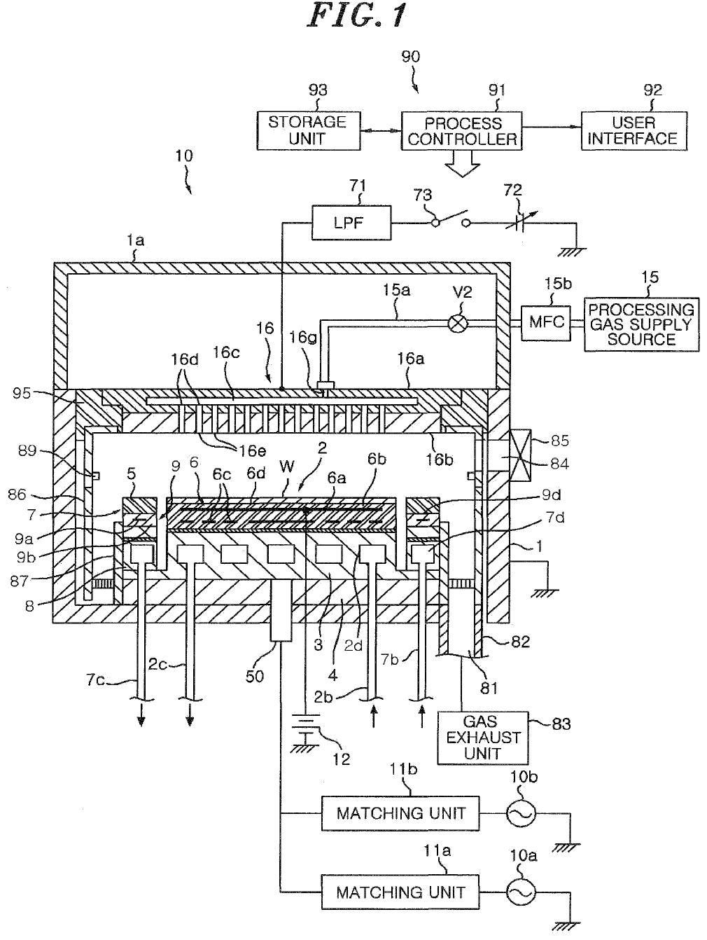

First, a schematic configuration of a plasma processing apparatus 10 according to an embodiment will be described. FIG. 1 is a schematic cross sectional view showing a schematic configuration of a plasma processing apparatus according to an embodiment. The plasma processing apparatus 10 has an airtight processing chamber 1 that is electrically grounded. The processing chamber 1 is formed in a cylindrical shape and made of, e.g., aluminum having an anodically oxidized surface. The processing chamber 1 defines a processing space where plasma is generated. A first mounting table 2 for horizontally supporting a wafer W as a target object is provided in the processing chamber 1.

The first mounting table 2 has a substantially columnar shape with an upper and a lower surface directed vertically. The upper surface of the first mounting table 2 serves as a mounting surface 6d on which the wafer W is mounted. The mounting surface 6d of the first mounting table 2 has substantially the same size as that of the wafer W. The first mounting table 2 includes a base 3 and an electrostatic chuck 6.

The base 3 is made of a conductive metal, e.g., aluminum having an anodically oxidized surface or the like. The base 3 serves as a lower electrode. The base 3 is supported by a supporting member 4 made of an insulator. The supporting member 4 is installed at a bottom portion of the processing chamber 1.

The electrostatic chuck 6 has a flat disc-shaped upper surface serving as the mounting surface 6d on which the wafer W is mounted. The electrostatic chuck 6 is provided at the center of the first mounting table 2 when seen from the top. The electrostatic chuck 6 includes an electrode 6a and an insulator 6b. The electrode 6a is embedded in the insulator 6b. A DC power supply 12 is connected to the electrode 6a. The wafer W is attracted and held on the electrostatic chuck 6 by a Coulomb force generated by applying a DC voltage from the DC power supply 12 to the electrode 6a. A heater 6c is provided in the insulator 6b of the electrostatic chuck 6. The heater 6c controls a temperature of the wafer W by a power supplied through a power supply unit to be described later.

A second mounting table 7 is provided around an outer peripheral surface of the first mounting table 2. The second mounting table 7 is formed in a cylindrical shape whose inner diameter is greater than an outer diameter of the first mounting table 2 by a predetermined value. The second mounting table 7 and the first mounting table 2 are coaxially arranged. The second mounting table 7 has an upper surface serving as a mounting surface 9d on which an annular focus ring 5 is mounted. The focus ring 5 is made of, e.g., single crystal silicon, and mounted on the second mounting table 7.

The second mounting table 7 includes a base 8 and a focus ring heater 9. The base 8 is made of the same conductive metal as that of the base 3, e.g., aluminum having an anodically oxidized surface. A lower portion of the base 3 which faces the supporting member 4 is greater in a diametrical direction than an upper portion of the base 3 and extends in a flat plate shape to a position below the second mounting base 7. The base 8 is supported by the base 3. The focus ring heater 9 is supported by the base 8. The focus ring heater 9 has an annular flat upper surface serving as a mounting surface 9d on which the focus ring 5 is mounted. The focus ring heater 9 has a heater 9a and an insulator 9b. The heater 9a is embedded in the insulator 9b. A power is supplied to the heater 9a through a power supply mechanism (not shown) to control a temperature of the focus ring 5. In this manner, the temperature of the wafer W and the temperature of the focus ring 5 are independently controlled by different heaters.

A power feed rod 50 for supplying RF (Radio Frequency) power is connected to the base 3. The power feed rod 50 is connected to a first RF power supply 10a via a first matching unit 11a and connected to a second RF power supply 10b via a second matching unit 11b. The first RF power supply 10a generates power for plasma generation. A high frequency power having a predetermined frequency is supplied from the first RF power supply 10a to the base 3 of the first mounting table 2. The second RF power supply 10b generates power for ion attraction (bias). A high frequency power having a predetermined frequency lower than that from the first RF power supply 10a is supplied from the second RF power supply 10b to the base 3 of the first mounting table 2.

A coolant path 2d is formed in the base 3. The coolant path 2d has one end connected to a coolant inlet line 2b and the other end connected to a coolant outlet line 2c. A coolant path 7d is formed in the base 8. The coolant path 7d has one end connected to a coolant inlet line 7b and the other end connected to a coolant outlet line 7c. The coolant path 2d is positioned below the wafer W and absorbs heat of the wafer W. The coolant path 7d is positioned below the focus ring 5 and absorbs heat of the focus ring 5. In the plasma etching apparatus 10, a temperature of the first mounting table 2 and that of the second mounting table 7 can be individually controlled by circulating a coolant, e.g., cooling water or the like, through the coolant path 2d and the coolant path 7d, respectively. Further, the plasma etching apparatus 10 may be configured such that a cold heat transfer gas is supplied to the backside of the wafer W and to a bottom surface of the focus ring 35 to separately control the temperatures thereof. For example, a gas supply line for supplying a cold heat transfer gas (backside gas) such as He gas or the like to a backside of the wafer W may be provided to penetrate through the first mounting table 2 and the like. The gas supply line is connected to a gas supply source. With this configuration, the wafer W attracted and held by the electrostatic chuck 6 on the top surface of the first mounting table 2 can be controlled to a predetermined temperature.

A shower head 16 serving as an upper electrode is provided above the first mounting table 2 to face the first mounting table 2 in parallel therewith. The shower head 16 and the first mounting table 2 function as a pair of electrodes (upper electrode and lower electrode).

The shower head 16 is provided at a ceiling wall portion of the processing chamber 1. The shower head 16 includes a main body 16a and an upper ceiling plate 16b serving as an electrode plate. The shower head 16 is supported at an upper portion of the processing chamber 1 through an insulating member 95. The main body 16a is made of a conductive material, e.g., aluminum having an anodically oxidized surface. The upper ceiling plate 16b is detachably held at a bottom portion of the main body 16a.

A gas diffusion space 16c is formed in the main body 16a. A plurality of gas holes 16d is formed in the bottom portion of the main body 16a to be positioned below the gas diffusion space 16c. Gas injection holes 16e are formed through the upper ceiling plate 16b in a thickness direction thereof. The gas injection holes 16e communicate with the gas holes 16d. With this configuration, the processing gas supplied to the gas diffusion space 16c is distributed in a shower form into the processing chamber 1 through the gas holes 16d and the gas injection holes 16e.

A gas inlet port 16g for introducing the processing gas into the gas diffusion space 16c is formed in the main body 16a. One end of a gas supply line 15a is connected to the gas inlet port 16g and the other end of the gas supply line 15a is connected to a processing gas supply source 15 for supplying a processing gas. A mass flow controller (MFC) 15b and an opening/closing valve V2 are disposed in the gas supply line 15a in that order from an upstream side. The processing gas for plasma etching is supplied from the processing gas supply source 15 to the gas diffusion space 16c through the gas supply line 15a and distributed in a shower form into the processing chamber 1 through the gas holes 16d and the gas injection holes 16e.

A variable DC power supply 72 is electrically connected to the shower head 16 serving as the upper electrode via a low pass filter (LPF) 71. A power supply of the variable DC power supply 72 is on-off controlled by an on/off switch 73. Current/voltage of the variable DC power supply 72 and on/off of the on/off switch 73 are controlled by a control unit 90 to be described later. As will be described later, when a plasma is generated in the processing space by applying the high frequency power from the first and the second RF power supply 10a and 10b to the first mounting table 2, the on/off switch 73 is turned on by the control unit 90 and a predetermined DC voltage is applied to the shower head 16 serving as the upper electrode, if necessary.

A cylindrical ground conductor 1a extends upward from a sidewall of the processing chamber 1 to a position higher than a height of the shower head 16. The cylindrical ground conductor 1a has a ceiling wall at the top thereof.

A gas exhaust port 81 is formed at a bottom portion of the processing chamber 1. A gas exhaust unit 83 is connected to the gas exhaust port 81 through a gas exhaust line 82. The first gas exhaust unit 83 has a vacuum pump. By operating the vacuum pump, a pressure in the processing chamber 1 can be decreased to a predetermined vacuum level. A loading/unloading port 84 for the wafer W is provided at a sidewall of the processing chamber 1. A gate valve 85 for opening/closing the loading/unloading port 84 is provided at the loading/unloading port 84.

A deposition shield 86 is provided along an inner surface of the sidewall of the processing chamber 1. The deposition shield 86 prevents etching by-products (deposits) from being attached to the inner wall of the processing chamber 1. A conductive member (GND block) 89 is provided at a portion of the deposition shield 86 at substantially the same height as the height of the wafer W. The conductive member 89 is connected such that a potential with respect to the ground can be controlled. Due to the presence of the conductive member 89, abnormal discharge is prevented. A deposition shield 87 extending along the first mounting table 2 is provided to correspond to a lower portion of the deposition shield 86. The deposition shields 86 and 87 are detachably provided.

The operation of the plasma processing apparatus 10 configured as described above is integrally controlled by the control unit 90. The control unit 90 includes: a process controller 91 having a CPU and configured to control the respective components of the plasma processing apparatus 100; a user interface 92; and a storage unit 93.

The user interface 92 includes a keyboard through which a process manager inputs commands to operate the plasma processing apparatus 10, a display for visualizing an operational state of the plasma processing apparatus 10, and the like.

The storage unit 93 stores therein recipes including a control program (software), processing condition data and the like for realizing various processes performed by the plasma processing apparatus 10 under the control of the process controller 91. If necessary, a recipe is retrieved from the storage unit 93 in response to a command from the user interface 92 or the like and executed by the process controller 91. Accordingly, a desired process is performed in the plasma processing apparatus 10 under the control of the process controller 91. The recipes including the control program, the processing condition data and the like can be stored in a computer-readable storage medium (e.g., a hard disk, a CD, a flexible disk, a semiconductor memory, or the like) or can be transmitted, when needed, from another apparatus through, e.g., a dedicated line, and used on-line.

(Configuration of First Mounting Table and Second Mounting Table)

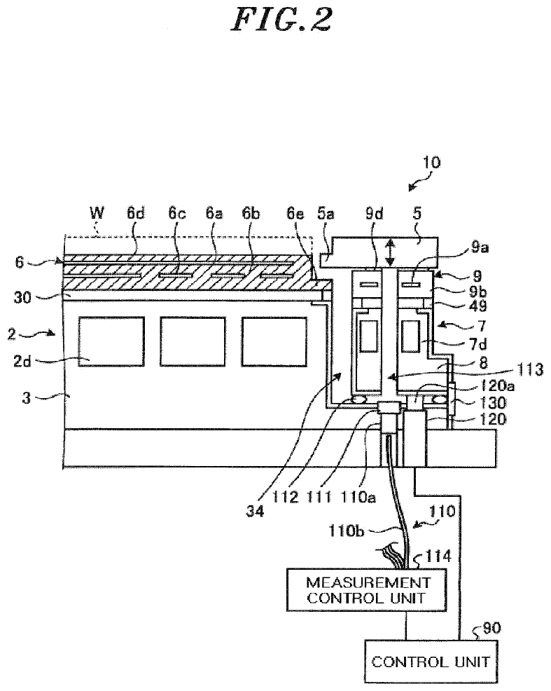

The configurations of principal parts of the first mounting table 2 and the second mounting table 7 according to a first embodiment will be described with reference to FIG. 2. FIG. 2 is a schematic cross sectional view showing the configuration of principal parts of the first mounting table and the second mounting table according to the first embodiment.

The first mounting table 2 includes a base 3 and an electrostatic chuck 6. The electrostatic chuck 6 is adhered to the base 3 through the insulating layer 30. The electrostatic chuck 6 is formed in a disc shape and provided coaxially with respect to the base 3. In the electrostatic chuck 6, an electrode 6a is provided in an insulator 6b. The upper surface of the electrostatic chuck 6 serves as the mounting surface 6d on which the wafer W is mounted. A flange portion 6e projecting outwardly in a radial direction of the electrostatic chuck 6 is formed at a lower end of the electrostatic chuck 6. In other words, the electrostatic chuck 6 has different outer diameters depending on positions of the side surface.

In the electrostatic chuck 6, the heater 6c is provided in the insulator 6b. The coolant path 2d is formed in the base 3. The coolant path 2d and the heater 6c function as a temperature control mechanism for controlling the temperature of the wafer W. The heater 6c may not be provided in the insulator 6b. For example, the heater 6c may be adhered to the lower surface of the electrostatic chuck 6 or may be interposed between the mounting surface 6d and the coolant path 2d. Further, a single heater 6c may be provided for the entire mounting surface 6d or may be provided for each of a plurality of divided regions of the mounting surface 6d. In other words, a plurality of heaters 6c may be provided for the respective divided regions of the mounting surface 6d. For example, the heater 6c may extend in an annular shape about the center of the first mounting table 2 in each of a plurality of regions concentrically arranged. Or, the heater may include a heater for heating a central region and a heater extending in an annular shape to surround the central region. The heater 6c may be provided in each of a plurality of regions obtained by radially dividing the region extending in an annular shape about the center of the mounting surface 6d.

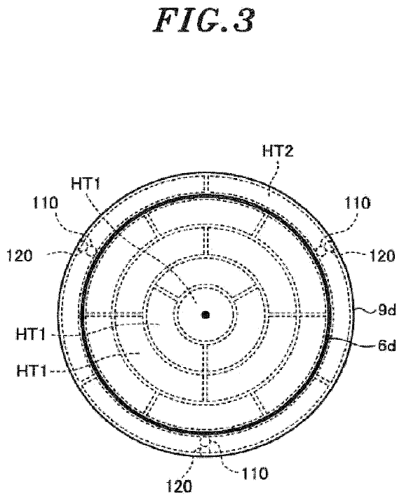

FIG. 3 is a top view of the first mounting table and the second mounting table which is viewed from the top. Referring to FIG. 3, the mounting surface 6d of the first mounting table 2 has a disc shape. The mounting surface 6d is divided into a plurality of regions HT1 depending on a distance and a direction from the center. The heater 6c is provided in each of the regions HT1. Accordingly, the plasma processing apparatus 10 can control a temperature of the wafer W in each of the regions HT1.

Referring back to FIG. 2, the second mounting table 7 includes the base 8 and the focus ring heater 9. The base 8 is supported by the base 3. In the focus ring heater 9, the heater 9a is provided in the insulator 9b. The coolant path 7d is formed in the base 8. The coolant path 7d and the heater 9a function as a temperature control mechanism for controlling a temperature of the focus ring 5. The focus ring heater 9 is adhered to the base 8 through an insulating layer 49. An upper surface of the focus ring heater 9 serves as the mounting surface 9d on which the focus ring 5 is mounted. A sheet member having high thermal conductivity or the like may be provided on the upper surface of the focus ring heater 9.

The focus ring 5 that is an annular member is provided coaxially with respect to the second mounting table 7. A protruding portion 5a is protruded in a radial direction from an inner side surface of the focus ring 5. In other words, the focus ring 5 has different inner diameters depending on positions of the inner side surface thereof. For example, an inner diameter of a portion of the focus ring 5 where the protruding portion 5a is not formed is greater than an outer diameter of the wafer W and an outer diameter of the flange portion 6e of the electrostatic chuck 6. On the other hand, an inner diameter of a portion of the focus ring 5 where the protruding portion 5a is formed is smaller than the outer diameter of the flange portion 6e of the electrostatic chuck 6 and greater than an outer diameter of a portion of the electrostatic chuck 6 where the flange portion 6e is not formed.

The focus ring 5 is disposed on the second mounting table 7 in a state where the protruding portion 5a is separated from an upper surface of the flange portion 6e of the electrostatic chuck 6 and also separated from a side surface of the electrostatic chuck 6. In other words, a gap is formed between a lower surface of the protruding portion 5a of the focus ring 5 and the upper surface of the flange portion 6e of the electrostatic chuck 6. In addition, a gap is formed between a side surface of the protruding portion 5a of the focus ring 5 and a side surface where the flange portion 6e of the electrostatic chuck 6 is not formed. The protruding portion 5a of the focus ring 5 is located above a gap 34 between the base 3 of the first mounting table 2 and the base 8 of the second mounting table 7. In other words, when viewed from a direction perpendicular to the mounting surface 6d, the protruding portion 5a overlaps with the gap 34 and covers the gap 34. Accordingly, it is possible to suppress inflow of the plasma into the gap 34.

The heater 9a has an annular shape coaxial with the base 8. A single heater 9a may be provided for the entire mounting surface 9d or may be provided for each of a plurality of divided regions of the mounting surface 9d. In other words, a plurality of heaters 9a may be provided for the respective divided regions of the mounting surface 9d. For example, the heater 9a may be provided in each of a plurality of regions obtained by circumferentially dividing the mounting surface 9d of the second mounting table 7. For example, in FIG. 3, the mounting surface 9d of the second mounting table 7 is provided around the disc-shaped mounting surface 6d of the first mounting table 2. The mounting surface 9d is circumferentially divided into a plurality of regions HT2, and the heater 9a is provided in each of the regions HT2. Accordingly, the plasma processing apparatus 10 can control a temperature of the focus ring 5 in each of the regions HT2.

Referring back to FIG. 2, the plasma processing apparatus 10 is provided with a measuring unit 110 for measuring a height of the upper surface of the focus ring 5. In the present embodiment, the measuring unit 110 constitutes an optical interferometer for measuring a distance by using interference of laser light and measures the height of the upper surface of the focus ring 5. The measuring unit 110 includes a light emitting part 110a and an optical fiber 110b. A light emitting part 110a is provided at the first mounting table 2 to be positioned below the second mounting table 7. A quartz window 111 for interrupting vacuum is provided at an upper portion of the light emitting part 110a. An O-ring 112 for interrupting vacuum is provided between the first mounting table 2 and the second mounting table 7. A hole 113 penetrating through the second mounting table 7 to the upper surface thereof is formed at a position corresponding to the position where the measuring unit 110 is provided. A member that transmits laser light may be provided at the hole 113.

The light emitting part 110a is connected to a measurement control unit 114 through the optical fiber 110b. The measurement control unit 114 has therein a light source for generating laser light for measurement. The laser light generated by the measurement control unit 114 is emitted from the light emitting part 110a through the optical fiber 110b. The laser light emitted from the light emitting part 110a is partially reflected by the quartz window 111 or the focus ring 5. The reflected laser light is incident on the light emitting part 110a.

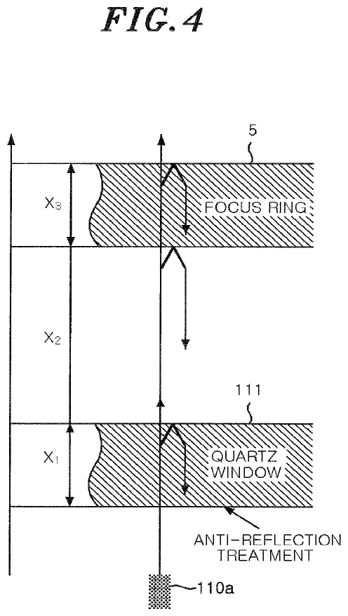

FIG. 4 shows a system of reflection of laser light. A surface of the quartz window 111 which faces the light emitting part 110a is subjected to anti-reflection treatment and, thus, the reflection of the laser light on that surface is reduced. As shown in FIG. 4, a part of the laser light emitted from the light emitting part 110a is mainly reflected on the upper surface of the quartz window 111, the lower surface of the focus ring 5 and the upper surface of the focus ring 5, and incident on the light emitting part 110a.

The light incident on the light emitting part 110a is guided to the measurement control unit 114 through the optical fiber 110b. The measurement control unit 114 has therein a spectrometer or the like and measures a distance based on the interference state of the reflected laser light. For example, the measurement control unit 114 detects an intensity of light for each mutual distance between reflective surfaces based on the interference state of the incident laser light.

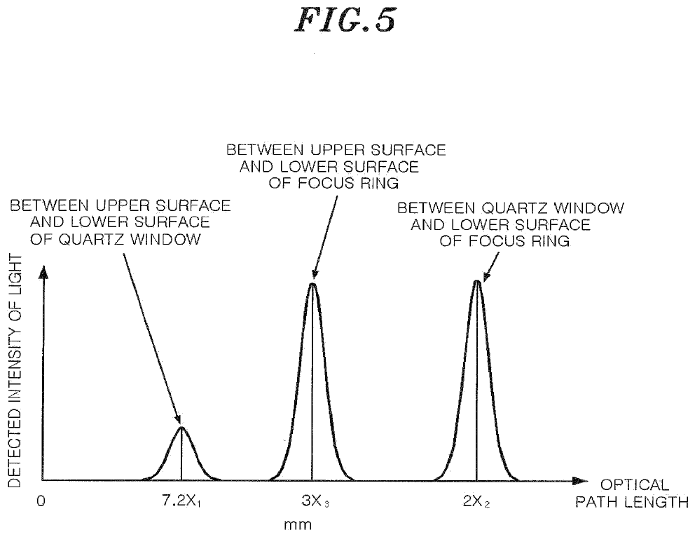

FIG. 5 shows an example of distribution of detected intensities of light. The measurement control unit 114 detects the intensity of the light while setting a mutual distance between the reflective surfaces as an optical path length. The horizontal axis in the graph of FIG. 5 represents the mutual distance set as the optical path length. “0” on the horizontal axis represents the origin of all mutual distances. The vertical axis in the graph of FIG. 5 represents the detected intensity of the light. The optical interferometer measures the mutual distance from the interference state of the reflected light. In the reflection, the light reciprocates the optical path of the mutual distance. Therefore, the optical path length is measured by “mutual distance×2×refractive index”. For example, when a thickness of the quartz window 111 is X₁ and the refractive index of quartz is 3.6, the optical path length to the upper surface of the quartz window 111 from the lower surface of the quartz window 111 is calculated as X₁×2×3.6=7.2X₁. In the example shown in FIG. 5, the intensity of the light reflected on the upper surface of the quartz window 111 has a peak at an optical path length of 7.2X₁. When a thickness of the hole 113 is X₂ and the refractive index of the hole 113 where air exists is 1.0, the optical path length to the lower surface of the focus ring 5 from the upper surface of the quartz window 111 is calculated as X₂×2×1.0=2X₂. In the example shown in FIG. 5, the intensity of the light reflected on the lower face of the focus ring 5 has a peak at an optical path length of 2X₂. When a thickness of the focus ring 5 made of silicon is X₃ and the refractive index of the focus ring 5 is 1.5, the optical path length to the upper surface of the focus ring 5 from the lower surface of the focus ring 5 is calculated as X₃×2×1.5=3X₃. In the example shown in FIG. 5, the intensity of the light reflected on the upper surface of the focus ring 5 has a peak at an optical path length of 3X₃.

The thickness and the material of a new focus ring 5 are known. The thickness and the refractive index of the material of the new focus ring 5 are registered in the measurement control unit 114. The measurement control unit 114 calculates an optical path length corresponding to the thickness and the refractive index of the material of the new focus ring 5 and measures the thickness of the focus ring 5 from a peak position of the light having the peak intensity near the calculated optical path length. For example, the measurement control unit 114 measures the thickness of the focus ring 5 from the peak position of the light having the peak intensity near the optical path length of 3X₃. The measurement control unit 114 outputs the measurement result to the control unit 90. The thickness of the focus ring 5 may be measured by the control unit 90. For example, the measurement control unit 114 measures the optical path length corresponding to the peak of the detected intensity and outputs the measurement result to the control unit 90. The thickness and the refractive index of the material of the new focus ring 5 are registered in the control unit 90. The control unit 90 may calculate the optical path length corresponding to the thickness and the refractive index of the material of the new focus ring 5 and measure the thickness of the focus ring 5 from the peak position of the light having the peak intensity near the calculated optical path length.

Referring back to FIG. 2, an elevation mechanism 120 for vertically moving the second mounting table 7 is provided at the first mounting table 2. For example, the elevation mechanism 120 is provided at the first mounting table 2 to be positioned below the second mounting table 7. The elevation mechanism 120 has therein an actuator and vertically moves the second mounting table 7 by extending/contracting a rod 120a by using driving force of the actuator. The elevation mechanism 120 may obtain driving force for extending/contracting the rod 120a by converting the driving force of the motor by a gear or the like or may obtain driving force for extending/contracting the rod 120a by a hydraulic pressure or the like.

In addition, the first mounting table 2 is provided with a conducting part 130 electrically connected to the second mounting table 7. The conducting part 130 is configured to electrically connect the first mounting table 2 and the second mounting table 7 even if the second mounting table 7 is vertically moved by the elevating mechanism 120. For example, the conducting part 130 is configured as a flexible wiring or a mechanism that is electrically connected by contact between a conductor and the base 8 even if the second mounting table 7 is vertically moved. The conducting part 130 is provided so that the second mounting table 7 and the first mounting table 2 have equal electrical characteristics. For example, a plurality of conducting parts 130 is provided on a circumferential surface of the first mounting table 2. The RF power supplied to the first mounting table 2 is also supplied to the second mounting table 7 through the conducting part 130. Alternatively, the conducting part 130 may be provided between the upper surface of the first mounting table 2 and the lower surface of the second mounting table 7.

In the plasma processing apparatus 10 of the present embodiment, three pairs of the measuring unit 110 and the elevation mechanism 120 are provided. For example, the pairs of the measuring unit 110 and the elevation mechanism 120 are arranged on the second mounting table 7 at a regular interval in a circumferential direction of the second mounting table 7. FIG. 3 shows arrangement positions of the measuring units 110 and the elevation mechanisms 120. The measuring unit 110 and the elevation mechanism 120 are disposed at the same position on the second mounting table 7 at an interval of 120° in the circumferential direction of the second mounting table 7. Four or more pairs of the measuring unit 110 and the elevation mechanism 120 may be provided on the second mounting table 7. Further, the measuring unit 110 and the elevation mechanism 120 may be separated in the circumferential direction of the second mounting table 7.

The measurement control unit 114 measures the thickness of the focus ring 5 at the positions of the measuring units 110 and outputs the measurement result to the control unit 90. The control unit 90 drives the elevation mechanisms 120 independently based on the measurement result so that the upper surface of the focus ring can be maintained at a predetermined height. For example, the control unit 90 vertically moves the elevation mechanisms 120 independently, based on the measurement result of the measuring unit 110, for each pair of the measuring unit 110 and the elevation mechanism 120. For example, the control unit 90 specifies a consumption amount of the focus ring 5 from the measured thickness of the focus ring 5 with respect to the thickness of the new focus ring 5 and raises the second mounting table 7 by controlling the elevation mechanism 120 based on the consumption amount. For example, the control unit 90 raises the second mounting table 7 by a distance corresponding to the consumption amount of the focus ring 5 by controlling the elevation mechanism 120.

The consumption amount of the focus ring 5 may vary in the circumferential direction of the second mounting table 7. As shown in FIG. 3, in the plasma processing apparatus 10, three or more pairs of the measuring unit 110 and the elevation mechanism 120 are provided; the consumption amount of the focus ring 5 at each arrangement position is specified; and the second mounting table 7 is raised by a distance corresponding to the consumption amount by controlling the elevation mechanism 120. Accordingly, the plasma processing apparatus 10 can align the position of the upper surface of the focus ring 5 with the upper surface of the wafer W in the circumferential direction. As a result, the plasma processing apparatus 10 can maintain the uniformity of etching characteristic in the circumferential direction.

(Operations and Effects)

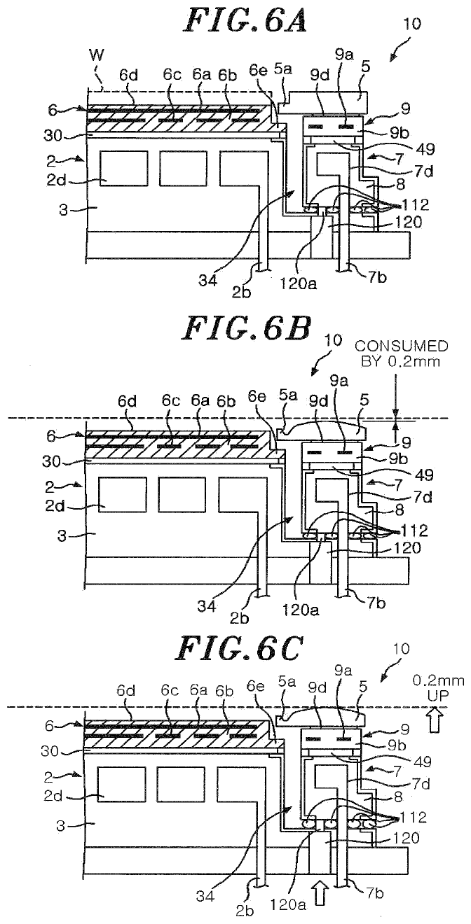

Next, operations and effects of the plasma processing apparatus 10 of the present embodiment will be described. FIGS. 6A to 6C explain an example of a sequence of raising the second mounting table. FIG. 6A shows a state in which a new focus ring 5 is mounted on the second mounting table 7. The height of the second mounting table 7 is adjusted so that the upper surface of the focus ring 5 is located at a predetermined height when the new focus ring 5 is mounted. For example, when the new focus ring 5 is mounted on the second mounting table 7, the height of the second mounting table 7 is adjusted so that the etching uniformity of the wafer W is obtained. As the wafer W is etched, the focus ring 5 is consumed. FIG. 6B shows a state in which the focus ring 5 is consumed. In the example shown in FIG. 6B, the upper surface of the focus ring 5 is consumed by 0.2 mm. The plasma processing apparatus 10 specifies the consumption amount of the focus ring 5 by measuring the height of the upper surface of the focus ring 5 by using the measuring unit 110. Then, the plasma processing apparatus 10 raises the second mounting table 7 based on the consumption amount by controlling the elevation mechanism 120. It is preferable to measure the height of the focus ring 5 when a temperature in the processing chamber 1 is stabilized at a level at which plasma processing is performed. The height of the focus ring 5 may be measured multiple times at a regular interval during the etching of a single wafer W, or may be performed once for a single wafer W, or may be performed once for a predetermined number of wafers W, or may be performed at an interval specified by a manager. FIG. 6C shows a state in which the second mounting table 7 is raised. In the example shown in FIG. 6C, the upper surface of the focus ring 5 is raised by 0.2 mm by raising the second mounting table 7 by 0.2 mm. The second mounting table 7 is configured not to be affected even if it is raised. For example, the coolant path 7d is configured as a flexible line or a mechanism that can supply a coolant even if the second mounting table 7 is vertically moved. The wiring for supplying a power to the heater 9a is configured as a flexible wiring or a mechanism that is electrically connected even if the second mounting table 7 is vertically moved.

Accordingly, in the plasma processing apparatus 10, even when the focus ring 5 is consumed, the deterioration in the etching characteristic in the outer peripheral portion of the wafer W can be suppressed and, further, the deterioration in the etching uniformity of the wafer W can be suppressed. Further, in the plasma processing apparatus 10, the second mounting table 7 is raised in a state where the focus ring 5 is mounted thereon. Accordingly, the heat input from the plasma into the focus ring 5 can be removed by the second mounting table 7. As a result, the plasma processing apparatus 10 can maintain a temperature of the focus ring 5 at a desired level, which makes it possible to suppress changes in the etching characteristics which are caused by the heat input from the plasma.

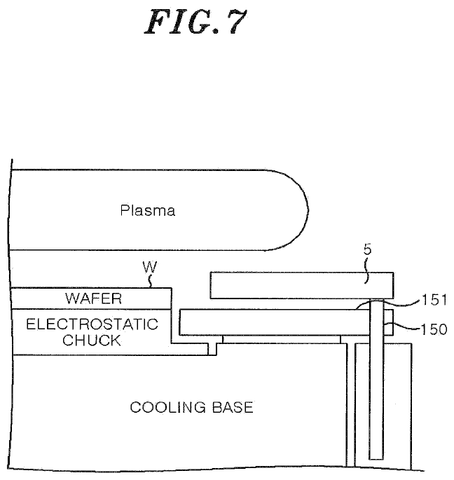

Hereinafter, the effect will be described by using a comparative example. FIG. 7 shows an example of a configuration of a comparative example. In the example shown in FIG. 7, only the focus ring 5 is raised by a drive mechanism 150 by a distance corresponding to the consumption amount of the focus ring 5. When the consumed focus ring 5 is raised, the focus ring 5 is separated from a mounting surface 151. When the focus ring 5 is separated from the mounting surface 151, the heat input from the plasma is not removed and the temperature of the focus ring 5 is increased, which may lead to changes in the etching characteristics. Further, when the focus ring 5 is separated from the mounting surface 151, the electrical characteristics such as an electrostatic capacitance, an impedance or the like or an applied voltage changes. Such electrical changes affect the plasma and the etching characteristic may change.

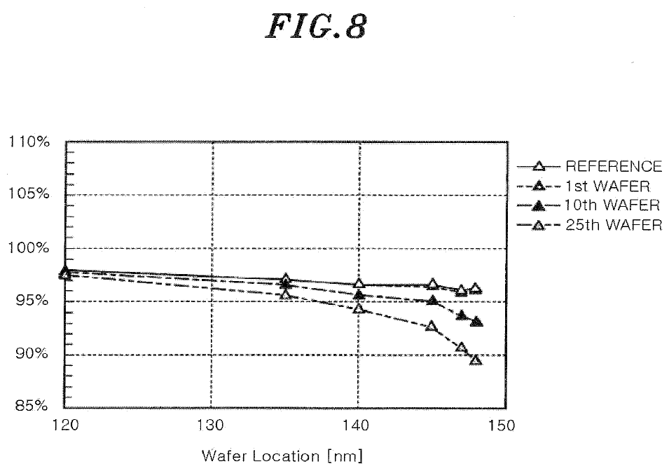

FIG. 8 shows an example of changes in the etching characteristics. In FIG. 8, the horizontal axis represents a distance from the center of the wafer W and the vertical axis represents an etching amount at locations separated from the center of the wafer W in the case of setting an etching amount at the center of the wafer W to 100%. FIG. 8 shows a reference graph of an etching amount for the wafer W. FIG. 8 further shows graphs of etching amounts of the first wafer, the tenth wafer and the 25th wafer in the case of continuously performing etching on the wafers W. The graph of the first wafer is close to the reference graph. On the other hand, the graph of the tenth wafer is far from the reference graph. The graph of the 25th wafer is farther from the reference graph compared to the case of the tenth wafer. This is because the temperature of the focus ring 5 is increased due to the heat input from the plasma. In other words, when the consumed focus ring 5 is raised as shown in FIG. 7, the etching uniformity of the wafer W can be maintained in the case of the first wafer. However, in the case of continuously performing the etching on the wafers W, the etching uniformity of the wafer W cannot be maintained.

On the other hand, in the plasma processing apparatus 10 of the present embodiment, the second mounting table 7 is raised in a state where the focus ring 5 is mounted thereon. Therefore, in the plasma processing apparatus 10, the heat input from the plasma into the focus ring 5 can be removed by the second mounting table 7. Accordingly, even when the etching is performed on the wafers W consecutively, the changes in the etching characteristics can be suppressed.

As described above, the plasma processing apparatus 10 includes: the first mounting table 2 on which the wafer W is mounted; and the second mounting table 7 provided around the first mounting table 2, on which the focus ring 5 is mounted, having therein the temperature control mechanism. In the plasma processing apparatus 10, the second mounting table 7 is vertically moved by the elevation mechanism 120. Accordingly, in the plasma processing apparatus 10, even when the focus ring 5 is vertically moved by vertically moving the second mounting table 7 by the elevation mechanism 120, the heat input from the plasma into the focus ring 5 can be removed by the second mounting table 7 and, thus, the deterioration in the uniformity of the plasma processing on the wafer W can be suppressed.

Further, in the plasma processing apparatus 10, the second mounting table 7 is electrically connected to the first mounting table 2. Therefore, in the plasma processing apparatus 10, even when the focus ring 5 is vertically moved by vertically moving the second mounting table 7 by the elevation mechanism 120, the changes in the electrical characteristics of the focus ring 5 and the applied voltage can be suppressed. Accordingly, the changes in the characteristics of the plasma can be suppressed.

The plasma processing apparatus 10 further includes the measuring unit 110 for measuring the height of the upper surface of the focus ring 5. In the plasma processing apparatus 10, the elevation mechanism 120 is driven such that the upper surface of the focus ring 5 is maintained within a preset range with respect to the upper surface of the wafer W. In the plasma processing apparatus 10, the change in the temperature of the focus ring 5 is suppressed by vertically moving the focus ring 5 by vertically moving the second mounting table 7 by the elevation mechanism 120. Further, in the plasma processing apparatus 10, the changes in the electrical characteristics of the focus ring 5 and the changes in the applied voltage are suppressed by electrically connecting the second mounting table 7 to the first mounting table 2. Therefore, in the plasma processing apparatus 10, the deterioration in the uniformity of the plasma processing on the wafer W can be suppressed simply by driving the elevating mechanism 120 such that the upper surface of the focus ring 5 is maintained within a preset range with respect to the upper surface of the wafer W.

Further, in the plasma processing apparatus 10, three or more pairs of the measuring unit 110 and the elevation mechanism 120 are provided on the second mounting table 7 and the upper surface of the focus ring 5 is maintained at a predetermined height. Accordingly, the plasma processing apparatus 10 can align the upper surface of the focus ring 5 with the upper surface of the wafer W in the circumferential direction. As a consequence, the plasma processing apparatus 10 can maintain the uniformity of the etching characteristics in the circumferential direction.

### Second Embodiment

Next, a second embodiment will be described. Since a schematic configuration of the plasma processing apparatus 10 according to the second embodiment is partially the same as that of the plasma processing apparatus 10 according to the first embodiment shown in FIG. 1, like reference numerals will be used for like parts and redundant description thereof will be omitted.

(Configurations of First Mounting Table and Second Mounting Table)

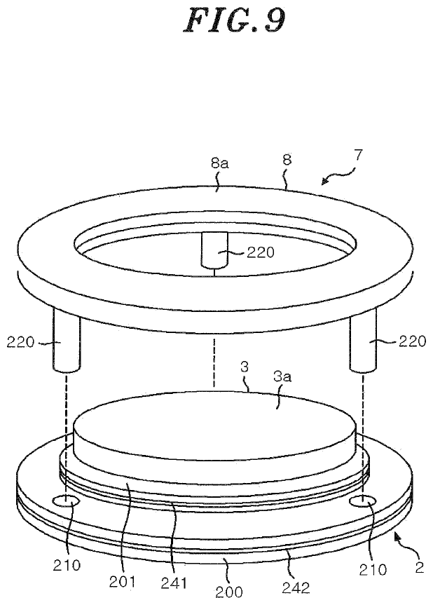

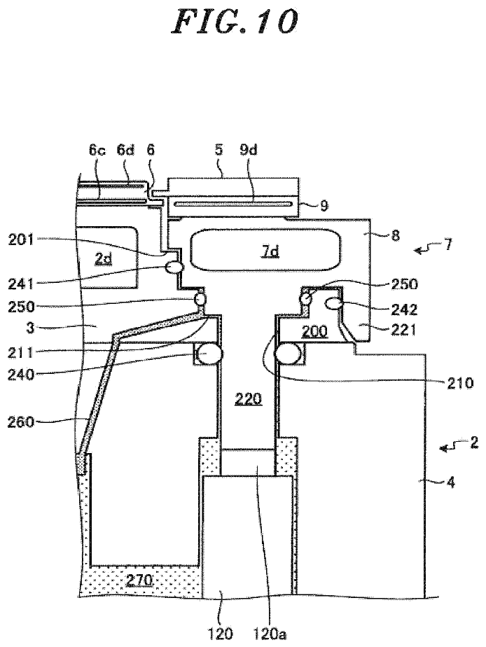

The configurations of principal parts of the first mounting table 2 and the second mounting table 7 will be described with reference to FIGS. 9 and 10. FIG. 9 is a perspective view showing the configurations of principal parts of the first mounting table and the second mounting table according to the second embodiment.

The first mounting table 2 includes a base 3. The base 3 is formed in a columnar shape, and the above-described electrostatic chuck 6 is provided on one surface 3a of the base 3a in an axial direction. The base 3 is provided with a flange portion 200 protruding outward along an outer periphery. In the base 3 of the present embodiment, an extended portion 201 extends outward from a peripheral side surface of the base 3 to have a larger outer diameter, and a flange portion 200 protrudes further outward from a lower portion of the extended portion. The flange portion 200 has holes 210 penetrating therethrough in the axial direction. The holes 210 are formed at three or more positions in the circumferential direction of the upper surface of the flange portion 200. The flange portion 200 of the present embodiment has three holes 210 spaced apart from each other at a regular interval in the circumferential direction.

The second mounting table 7 includes a base 8. The base 8 is formed in a cylindrical shape whose inner diameter is greater than an outer diameter of the surface 3a of the base 3 by a predetermined size. The above-described focus ring heater 9 is provided on one surface 8a of the base 8 in an axial direction. The base 8 has columnar portions 220 spaced apart from the same interval as that of the holes 210 of the flange portion 200. Three columnar portions 220 are formed on the bottom surface of the base 8 of the present embodiment at a regular interval in the circumferential direction.

The base 8 and the base 3 are coaxially disposed on the flange portion 200 of the base 3 while aligning positions thereof in the circumferential direction so that the columnar portions 220 can be inserted into the holes 210.

FIG. 10 is a schematic cross sectional view showing the configuration of the principal parts of the first mounting table and the second mounting table according to the second embodiment. FIG. 10 shows cross sections of the first mounting table 2 and the second mounting table 7 at the position of the hole 210.

The base 3 is supported by a supporting member 4 made of an insulating material. The hole 210 is formed in the base 3 and the supporting member 4.

The diameter of the hole 210 is smaller at a lower portion than at an upper portion. As a consequence, a step 211 is formed. The diameter of the columnar portion 220 is smaller at a lower portion than at an upper portion to correspond to the hole 210.

The base 8 is disposed on the flange portion 200 of the base 3. An outer diameter of the base 8 is greater than that of the base 3. An annular portion 221 protruding downward is formed at a portion of the lower surface of the base 8 which faces the base 3 and is positioned beyond an outer diameter of the base 3. When the base 8 is disposed on the flange portion 200 of the base 3, the annular portion 221 covers a side surface of the flange portion 200.

The columnar portions 220 are inserted into the holes 210. An elevation mechanism 120 for vertically moving the second mounting table 7 is provided below each of the holes 210. For example, the base 3 is provided with the elevation mechanism 120 for vertically moving the columnar portion 220. The elevation mechanism 120 has therein an actuator and vertically moves the columnar portion 220 by extending/contracting the rod 120a by driving force of the actuator.

A seal member is provided at the hole 210. For example, a seal 240 such as an O-ring or the like is provided on the surface of the hole 210 which faces the columnar portion 220 along a circumferential direction of the hole 210. The seal 240 is in contact with the columnar portion 220. In addition, a seal member is provided between surfaces of the base 8 and the base 3 which are in parallel in an axial direction. For example, in the base 3, a seal 241 is provided on a side surface of the extended portion 201 along the circumferential surface. In the base 3, a seal 242 is provided on a side surface of the flange portion 200 along the circumferential surface.

The base 3 is provided with a conducting portion 250 electrically connected to the base 8. The conducting portion 250 is formed at a part of a peripheral surface of the hole 210 near the step 211. The conducting portion 250 is configured to electrically connect the base 3 and the base 8 even if the base 8 is vertically moved by the elevation mechanism 120. For example, the conducting portion 250 is configured as a flexible wiring or a mechanism that is electrically connected by contact between a conductor and the base 8 even if the base 8 is vertically moved. The conducting portion 250 is provided so that the base 3 and the base 8 have equal electrical characteristics.

In addition, the base 3 is provided with a conduit 260 connected to an inner lower portion of the base 3 at the step 211 of the hole 210. The conduit 260 is connected to a vacuum pump (not shown). The vacuum pump may be provided at the first gas exhaust unit 83 or may be provided separately. In the plasma processing apparatus 10 according to the second embodiment, a pressure in a space formed by the seals 240 to 242 between the base 8 and the base 3 is decreased by performing evacuation through the conduit 260 by operating the vacuum pump.

A pressure in a space below the first mounting table 2 is set to at atmospheric pressure. For example, a space 270 is formed at an inner lower portion of the supporting member 4 and a pressure therein is set to an atmospheric pressure. The hole 210 communicates with the space 270. In the plasma processing apparatus 10, the hole 210 is sealed by the seal 240 and, thus, the introduction of the atmospheric pressure in the base 3 into the processing chamber 1 is suppressed.

In the plasma processing apparatus 10, when the columnar portion 220 is vertically moved by the elevation mechanism 120, air is introduced from the seal 240 by the movement of the columnar portion 220.

Therefore, in the plasma processing apparatus 10, a the pressure in the space formed by the seals 240 to 242 between the base 8 and the base 3 is decreased by performing evacuation through the conduit 260.

Accordingly, in the plasma processing apparatus 10, it is possible to suppress introduction of air from the seal 240 into the processing chamber 1. Further, in the plasma processing apparatus 10, even when particles are generated in the conducting portion 250 or the like, it is possible to suppress introduction of particles into the processing chamber 1 by performing evacuation through the conduit 260 or the like.

Further, in the plasma processing apparatus 10, the pressure in the space formed by the seals 240 to 242 between the base 8 and the base 3 is decreased by sealing the hole 210 by the seal 240 and performing evacuation through the conduit 260. As a consequence, reaction force of the atmospheric pressure is applied only to an area of the base 3 which corresponds to the columnar portion 220. For example, the reactive force of the atmospheric pressure is about 200 kgf when the evacuation through the conduit 260 is not performed. However, when the evacuation is performed through the conduit 260, the reaction force is reduced to about 15 kgf. Therefore, a load of the actuator of the elevation mechanism 120 at the time of vertically moving the second mounting table 7 can be reduced.

The first mounting table 2 is provided with the flange portion 200 protruding outward along the outer periphery. The flange portion 200 has the holes 210 formed at three or more positions thereof while penetrating therethrough in the axial direction. The second mounting table 7 is disposed on the upper portion of the flange portion 200 along the outer periphery of the first mounting table 2. The columnar portions 220 to be inserted into the holes 210 are formed at positions of the lower surface of the second mounting table 7 facing the flange portion 200 which correspond to the positions of the holes 210. The elevating mechanism 120 vertically moves the second mounting table 7 by moving the columnar portion 220 in the axial direction with respect to the hole 210. In the plasma processing apparatus 10, a first seal member (the seal 240) is provided at the hole 210 to contact with the columnar portions 220 and seal the hole 210. In the plasma processing apparatus 10, second seal members (the seals 241 and 242) for sealing a space the first mounting table 2 and the second mounting table 7 are provided surfaces of the first mounting table 2 and the second mounting table 7 which are in parallel to each other in the axial direction. The plasma processing apparatus 10 includes a depressurization unit (the conduit 260 and the vacuum pump) for depressurizing the space formed by the first seal member and the second seal members between the first mounting table 2 and the second mounting table 7. Accordingly, the plasma processing apparatus 10 according to the second embodiment can suppress the introduction of air into the processing chamber 1 and also can suppress the introduction of particles into the processing chamber 1. In addition, the plasma processing apparatus 10 can reduce the load of the actuator of the elevation mechanism 120 at the time of vertically moving the second mounting table 7.

While various embodiments have been described, various modifications can be made without being limited to the above-described embodiments. For example, the above-described plasma processing apparatus 10 is a capacitively coupled plasma processing apparatus 10. However, it is possible to employ any plasma processing apparatus 10. For example, the plasma processing apparatus 10 may be any type of plasma processing apparatus 10, such as an inductively coupled plasma processing apparatus 10 or a plasma processing apparatus 10 for exciting a gas by a surface wave such as a microwave.

In the above-described embodiments, the case in which the first mounting table 2 and the second mounting table 7 are electrically connected by the conducting part 130 has been described as an example. However, the present disclosure is not limited thereto. For example, the second mounting table 7 may be electrically connected to an RF power supply for supplying RF power to the first mounting table 2. For example, the second mounting table 7 may be supplied with RF power supplied from the first matching unit 11a and the second matching unit 11b.

Further, in the above-described embodiments, the case in which the second mounting table 7 is provided with the coolant path 7d and the heater 9a constituting the temperature control mechanism for controlling a temperature of the focus ring 5 has been described as an example. However, the present disclosure is not limited thereto. For example, only one of the coolant path 7d and the heater 9a may be provided at the second mounting table 7. The temperature control mechanism is not limited to the coolant path 7d and the heater 9a and may vary as long as it can control the temperature of the focus ring 5.

In the above-described embodiment, the case in which the second mounting table 7 is raised by the distance corresponding to the consumption amount of the upper surface of the focus ring 5 has been described as an example. However, the present disclosure is not limited thereto. For example, in the plasma processing apparatus 10, the position of the focus ring 5 with respect to the wafer W may be changed by vertically moving the second mounting table 7 depending on types of plasma processing to be performed. For example, in the plasma processing apparatus 10, the position of the focus ring 5 for each type of plasma processing is stored in the storage unit 93. The process controller 91 may read out from the storage unit 93 the position of the focus ring 5 corresponding to the type of the plasma processing to be performed and vertically move the focus ring 5 to the read-out position by vertically moving the second mounting table 7. Further, the plasma processing apparatus 10 may change the position of the focus ring 5 with respect to the wafer W by vertically moving the second mounting table 7 during processing of a single wafer. For example, the plasma processing apparatus 10 stores the position of the focus ring 5 in the storage unit 93 for each type of plasma processing. The process controller 91 may read out from the storage unit 93 the position of the focus ring 5 for each type of plasma processing to be performed and vertically move the second mounting table 7 depending on the process to be performed during the plasma processing to thereby vertically move the focus ring 5 to a position corresponding to the process to be performed.

While the disclosure has been shown and described with respect to the embodiments, it will be understood by those skilled in the art that various changes and modifications may be made without departing from the scope of the disclosure as defined in the following claims.

What is claimed is:

1. A plasma processing apparatus comprising:
a first mounting table on which a target object to be processed is mounted;
a second mounting table, provided around the first mounting table, on which a focus ring is mounted, the second mounting table having therein a temperature control mechanism; and
an elevation mechanism configured to vertically move the second mounting table.

2. The plasma processing apparatus of claim 1, wherein the second mounting table is electrically connected to the first mounting table or to an RF (Radio Frequency) power supply configured to supply RF power to the first mounting table.

3. The plasma processing apparatus of claim 1, further comprising:
a measuring unit configured to measure a height of an upper surface of the focus ring,
wherein the elevation mechanism is driven such that the upper surface of the focus ring is maintained within a preset range with respect to an upper surface of the target object.

4. The plasma processing apparatus of claim 3, wherein three or more pairs of the elevation mechanism and the measuring unit are provided on the second mounting table and independently driven such that the upper surface of the focus ring is maintained at a predetermined height.

5. The plasma processing apparatus of claim 1, wherein the first mounting table is provided with a flange portion protruding outward along an outer periphery and having holes formed at three or more positions in a circumferential direction while penetrating therethrough in an axial direction of the first mounting table,
the second mounting table is provided on an upper portion of the flange portion along the outer periphery of the first mounting table and has columnar portions, to be inserted into the respective holes, at positions of a lower surface thereof facing the flange portion that correspond to the positions of the holes,
the elevation mechanism vertically moves the second mounting table by moving the columnar portions in the axial direction with respect to the holes, and
the plasma processing apparatus further comprises:
a first seal member provided at each of the holes and configured to seal the hole while being in contact with the corresponding columnar portion;
a second seal member provided between surfaces of the first mounting table and the second mounting table, which are in parallel in the axial direction, to seal a gap between the first mounting table and the second mounting table; and
a depressurization unit configured to depressurize a space formed by the first seal member and the second seal member between the first mounting table and the second mounting table.
